(19) United States
(12) Patent Application Publication
(10) Pub. No.: US 2023/0206122 A1
(43) Pub. Date: Jun. 29, 2023

(54) APPARATUS AND METHOD FOR REINFORCEMENT LEARNING BASED ON USER LEARNING ENVIRONMENT IN SEMICONDUCTOR DESIGN

(71) Applicant: AGILESODA INC., Seoul (KR)

(72) Inventors: Pham-Tuyen LE, Suwon-si (KR); Ye-Rin MIN, Namyangju-si (KR); JunHo KIM, Seoul (KR); DoKyoon YOON, Seoul (KR); KyuWon CHOI, Seongnam-si (KR)

(73) Assignee: AGILESODA INC., Seoul (KR)

(21) Appl. No.: 18/074,749

(22) Filed: Dec. 5, 2022

(30) Foreign Application Priority Data
Dec. 28, 2021 (KR) 10-2021-0190142

(51) Int. Cl. G06N 20/00; G06F 30/327; G06F 30/3308

(52) U.S. Cl. CPC G06N 20/00; G06F 30/327; G06F 30/3308

(57) ABSTRACT

Disclosed are an apparatus and a method for reinforcement learning based on a user learning environment in semiconductor design. According to the present disclosure, a user may configure a learning environment in semiconductor design and may determine optimal positions of semiconductor elements and standard cells through reinforcement learning using simulation, and reinforcement learning may be performed based on the learning environment configured by the user, thereby automatically determining optimized semiconductor element positions in various environments.

### CROSS-REFERENCE TO RELATED APPLICATION(S)

This application is based on and claims priority under 35 U.S.C. 119 to Korean Patent Application No. 10-2021-0190142, filed on Dec. 28, 2021, in the Korean Intellectual Property Office, the disclosure of which is herein incorporated by reference in its entirety.

### BACKGROUND OF THE INVENTION

### 1. Field of the Invention

The present disclosure relates to an apparatus and a method for reinforcement learning based on a user learning environment in semiconductor design and, more specifically, to an apparatus and a method for reinforcement learning based on a user learning environment, wherein optimal positions of semiconductor elements are determined through reinforcement learning using simulation on a learning environment configured by the user.

### 2. Description of the Prior Art

Reinforcement learning refers to a learning method that handles an agent who interacts with an environment and accomplishes an objective, and is widely used in the artificial intelligence field.

The purpose of such reinforcement learning is to find out what behavior a reinforcement learning agent (subject of learning behaviors) needs to do such that more rewards are given thereto.

That is, it is learned what is to be done to maximize rewards even without fixed answers. Instead of hearing what behavior is to be done in advance and then doing the same in situation having a clear relation between input and output, processes for learning how to maximize rewards through trial and error are undertaken.

In addition, the agent selects successive actions as time steps elapse, and will be rewarded based on the influence exerted on the environment by the actions.

FIG. 1 is a block diagram illustrating the configuration of a reinforcement learning apparatus according to the prior art. As illustrated in FIG. 1, the agent 10 learns a method for determining an action A (or behavior) by learning a reinforcement learning model, each action A influences the next state S, and the degree of success may be measured in terms of the reward R.

That is, the reward is a point of reward for the action (behavior) determined by the agent 10 according to a specific state when learning proceeds through a reinforcement learning model, and is a kind of feedback related to the decision making by the agent 10 as a result of learning.

The environment 20 is a set of rules related to behaviors that the agent 10 may take, rewards therefor, and the like. States, actions, and rewards constitute the environment, and everything determined, except the agent 10, corresponds to the environment.

Meanwhile, the agent 10 takes actions to maximize future rewards through reinforcement learning, and the result of learning is heavily influenced by how the rewards are determined.

However, such reinforcement learning has a problem in that there is a difference between the actual environment and the simulated virtual environment such that, when a semiconductor element is to be disposed under various conditions during a semiconductor design process, there is a difference between the actual environment in which the operator manually finds out the optimal position and conduct design and the virtual environment, thereby failing to optimize learned actions.

There is another problem in that it is difficult to customize the reinforcement learning environment before the users start reinforcement learning, and to perform reinforcement learning based on the resulting environment configuration.

Moreover, a large amount of costs (time, manpower, and the like) is necessary to fabricate a virtual environment that emulates the actual environment well, and it is difficult to quickly reflect the changing actual environment.

There is another problem in that when a semiconductor element is disposed under various conditions during an actual semiconductor design process that has been learned through the virtual environment, learned actions fail to be optimized due to a difference between the actual environment and the virtual environment.

Therefore, it is critical to make an optimized virtual environment, and there is a need for a technology for quickly reflecting the changing actual environment.

### SUMMARY OF THE INVENTION

In order to solve the above-mentioned problems, it is an aspect of the present disclosure to provide an apparatus and a method for reinforcement learning based on a user learning environment in semiconductor design, wherein a user configures a learning environment and determines optimal positions of semiconductor elements through reinforcement learning that uses simulation.

In accordance with an aspect of the present disclosure, an apparatus for reinforcement learning based on a user learning environment in semiconductor design according to an embodiment may include: a simulation engine configured to analyze object information including a semiconductor element and a standard cell based on design data including semiconductor netlist information, configure a customized reinforcement learning environment by adding constraint or position change information with regard to each object through configuration information input from a user terminal and the analyzed object information, perform reinforcement learning based on the customized reinforcement learning environment, perform simulation based on an action determined to optimize disposition of at least one semiconductor element and standard cell, and state information of the customized reinforcement learning environment, and provide reward information calculated based on connection information of semiconductor elements and standard cells according to a simulation result as feedback regarding decision making by a reinforcement learning agent; and a reinforcement learning agent configured to perform reinforcement learning based on state information and reward information received from the simulation engine, thereby determining an action so as to optimize disposition of semiconductor elements and standard cells, wherein the simulation engine distinguishes semiconductor elements, standard cells, and wires according to characteristics or functions, and distinguishes, based on addition of specific colors, the objects distinguished according to characteristics or functions, thereby preventing learning ranges from increasing during reinforcement learning, and wherein the reinforcement learning agent determines an action, by reflecting distances between semiconductor elements and lengths of wires connecting semiconductor elements and standard cells, through learning using a reinforcement learning algorithm such that the semiconductor elements and the standard cells are disposed in optimal positions.

In addition, according to the embodiment, the design data may be a semiconductor data file including CAD data or netlist data.

In addition, according to the embodiment, the simulation engine may include: an environment configuration portion configured to add object-specific constraint or position change information included in design data through configuration information input from the user terminal, distinguish semiconductor elements, standard cells, and wires according to characteristics or functions so as to prevent learning ranges from increasing during reinforcement learning, and distinguish, based on addition of specific colors, the objects distinguished according to characteristics or functions, thereby configuring a customized reinforcement learning environment; a reinforcement learning environment configuration portion configured to analyze object information including semiconductor elements and standard cells based on design data including semiconductor netlist information, generate simulation data constituting a customized reinforcement learning environment by adding constraint or position change information configured by the environment configuration portion, and request, based on the simulation data, the reinforcement learning agent to provide optimization information for disposition of at least one semiconductor element and standard cell; and a simulation portion configured to perform simulation constituting a reinforcement learning environment regarding disposition of semiconductor elements and standard cells, based on actions received from the reinforcement learning agent, and state information including semiconductor element disposition information to be used for reinforcement learning, and provide the reinforcement learning agent with reward information calculated based on connection information of semiconductor elements and standard cells simulated as feedback regarding decision making by the reinforcement learning agent.

In addition, according to an embodiment of the present disclosure, a method for reinforcement learning based on a user learning environment may include the steps of: a) receiving, by a reinforcement learning server, design data including semiconductor netlist information from a user terminal; b) analyzing, by the reinforcement learning server, object information including a semiconductor element and a standard cell from the received design data, and configuring a customized reinforcement learning environment by adding constraint or position change information with regard to each object through configuration information input from a user terminal, and the analyzed object information; c) performing, by the reinforcement learning server, reinforcement learning based on reward information and state information of the customized reinforcement learning environment including disposition information of semiconductor elements and standard cells to be used for reinforcement learning through a reinforcement learning agent, thereby determining an action so as to optimize disposition of at least one semiconductor element disposition and stand cell disposition; and d) performing, by the reinforcement learning server, simulation constituting a reinforcement learning environment regarding disposition of the semiconductor element and standard cell based on an action, and generating reward information calculated based on connection information of semiconductor elements and standard cells according to a result of performing simulation as feedback regarding decision making by the reinforcement learning agent, wherein the customized reinforcement learning environment configured in step b) distinguishes semiconductor elements, standard cells, and wires according to characteristics or functions so as to prevent learning ranges from increasing during reinforcement learning, and distinguishes, based on addition of specific colors, the objects distinguished according to characteristics or functions, and wherein, in step c), the reinforcement learning server determines an action, by reflecting distances between semiconductor elements and lengths of wires connecting semiconductor elements and standard cells, through learning using a reinforcement learning algorithm such that the semiconductor elements and the standard cells are disposed in optimal positions.

In addition, according to the embodiment, the design data in step a) may be a semiconductor data file including CAD data or netlist data.

According to the present disclosure, a user may upload semiconductor data and may easily configure a reinforcement learning environment such that the reinforcement learning environment is quickly constructed.

In addition, the present disclosure is advantageous in that reinforcement learning is conducted based on a learning environment configured by the user, thereby automatically determining optimized positions of standard cells and semiconductor elements in various environments.

### BRIEF DESCRIPTION OF THE DRAWINGS

The above and other aspects, features and advantages of the present disclosure will be more apparent from the following detailed description taken in conjunction with the accompanying drawings, in which:

FIG. 1 is a block diagram illustrating the configuration of a conventional reinforcement learning apparatus;

FIG. 2 is a block diagram illustrating an apparatus for reinforcement learning based on a user learning environment in semiconductor design according to an embodiment of the present disclosure;

FIG. 3 is a block diagram illustrating a reinforcement learning server of the apparatus for reinforcement learning based on a user learning environment in semiconductor design according to the embodiment in FIG. 2;

FIG. 4 is a block diagram illustrating the configuration of the reinforcement learning server according to the embodiment in FIG. 3; and

FIG. 5 is a flowchart illustrating a method for reinforcement learning based on a user learning environment in semiconductor design according to an embodiment of the present disclosure.

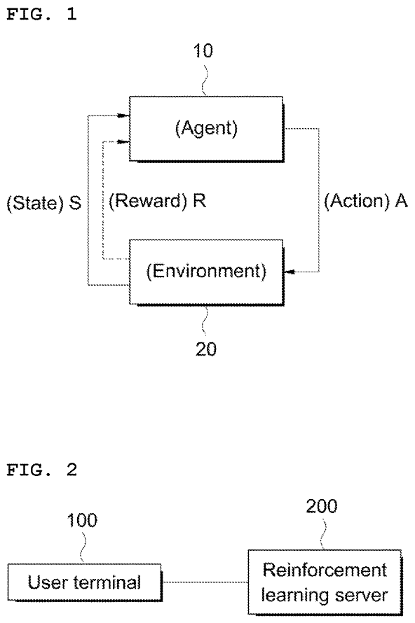

### DETAILED DESCRIPTION OF THE EXEMPLARY EMBODIMENTS

Hereinafter, the present disclosure will be described in detail with reference to exemplary embodiments of the present disclosure and the accompanying drawings, assuming that identical reference numerals in the drawings denote identical elements.

Prior to detailed descriptions for implementing the present disclosure, it is to be noted that elements having no direct relevance to the technical gist of the present disclosure will be omitted without obscuring the technical gist of the present disclosure.

In addition, terms or words used in the present specification and claims are to be interpreted in meanings and concepts conforming to the technical idea of the present disclosure according to the principle that the inventors may define appropriate concepts of terms to better describe the present disclosure.

As used herein, the description that a part “includes” an element means, without excluding other elements, that the part may further include other elements.

In addition, terms such as “ . . . portion”, “-er”, and “ . . . module” refer to units configured to process at least one function or operation, and may be distinguished by hardware, software, or a combination of the two.

In addition, the term “at least one” is defined as including both singular and plural forms, and it will be obvious that, even without the term “at least one”, each element may exist in a singular or plural form, and may denote a singular or plural form.

In addition, each element provided in a singular or plural form may be changed depending on the embodiment. Hereinafter, an exemplary embodiment of an apparatus and a method for reinforcement learning based on a user learning environment according to an embodiment of the present disclosure will be described in detail with reference to the accompanying drawings.

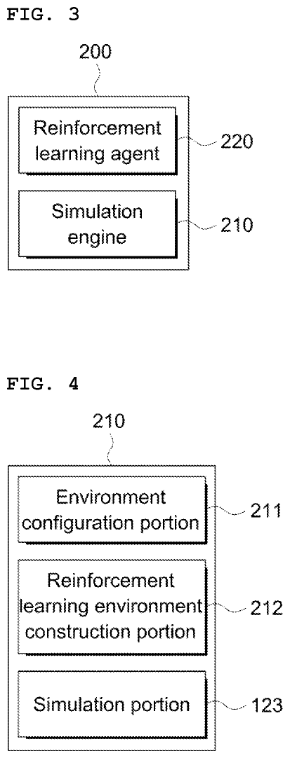

FIG. 2 is a block diagram illustrating an apparatus for reinforcement learning based on a user learning environment in semiconductor design according to an embodiment of the present disclosure. FIG. 3 is a block diagram illustrating a reinforcement learning server of the apparatus for reinforcement learning based on a user learning environment in semiconductor design according to the embodiment in FIG. 2. FIG. 4 is a block diagram illustrating the configuration of the reinforcement learning server according to the embodiment in FIG. 3.

Referring to FIG. 2 to FIG. 4, an apparatus for reinforcement learning based on a user learning environment in connection with semiconductor design according to an embodiment of the present disclosure may include a reinforcement learning server 200 which analyzes information regarding an object such as a semiconductor element or a standard cell, and which configures a customized reinforcement learning environment by adding specific constraint or position change information, based on configuration information input from a user terminal and the analyzed object information, with regard to each object.

In addition, the reinforcement learning server 200 may include a simulation engine 210 and a reinforcement learning agent 220 so as to perform simulation based on the customized reinforcement learning environment, and to perform reinforcement learning by using reward information regarding disposition of a target object simulated based on an action determined to optimize disposition of a semiconductor element, a standard cell, or the like, and state information of the customized reinforcement learning environment.

The simulation engine 210 receives design data including semiconductor netlist information from a user terminal 100 that has access through a network, and analyzes information regarding an object such as an IC including logic elements, such as semiconductor elements and stand cells, included in the received semiconductor design data.

The user terminal 100 can access the reinforcement learning server 200 through a web browser and can upload a specific pieces of design data stored in the user terminal 100 into the reinforcement learning server 200. The user terminal 100 may be a desktop PC, a laptop PC, a tablet PC, a PDA, or an embedded terminal.

In addition, the user terminal 100 may have an application program installed therein such that design data uploaded into the reinforcement learning server 200 can be customized based on configuration information input by the user.

The design data refers to data including semiconductor netlist information, and may include information regarding logic elements such as semiconductor elements, standard cells, and the like, which will enter a reinforcement learning state.

In addition, the netlist is a result obtained after circuit synthesis, and enumerates information regarding specific design elements and connectivity thereof. The same is used by circuit designers to make a circuit that satisfies a desired function. However, it is also possible to use a hardware description language (HDL) to implement the same, or to manually draw a circuit with a CAD tool.

If the HDL language is used, the same is used in a method easy to implement from laymen's point of view. Therefore, when actually applied to hardware, for example, when implemented as a chip, a circuit synthesis process is performed. The input and output of constituent elements, and the type of adder used thereby are referred to as a netlist. The result of synthesis may be output as a single file, which is referred to as a netlist file.

In addition, a circuit itself may be expressed as a netlist file when a CAD tool is used.

In addition, design data may include individual files because individual constraints need to be configured after receiving information regarding respective objects, such as semiconductor elements and standard cells. The design data may preferably be configured as a semiconductor data file. The file type may be as follows: “.v” file, “ctl” file, or the like, which is composed by an HDL used for electronic circuits and systems.

In addition, the design data may be a semiconductor data file composed by the user such that a learning environment similar to the actual environment can be provided, or may be CAD data.

In addition, the simulation engine 210 may construct a reinforcement learning environment by implementing a virtual environment for learning while interacting with the reinforcement learning agent 120, and may have an API configured therein such that a reinforcement learning algorithm for reinforcing a model of the reinforcement learning agent 120 can be applied.

The API may deliver information to the reinforcement learning agent 120, and may perform an interface between programs, such as “Python”, for the reinforcement learning agent 120.

In addition, the simulation engine 210 may include a web-based graphic library (not illustrated) such that web-based visualization is possible.

That is, the simulation engine 210 may be configured such that interactive 3D graphics can be used in a compatible web browser.

In addition, the simulation engine 210 may configure a customized reinforcement learning environment by adding specific constraint or position change information to analyzed objects, based on configuration information input from the user terminal 100, with regard to each object.

In addition, the simulation engine 210 may perform simulation based on the customized reinforcement learning environment, and may provide reward information regarding the disposition of a semiconductor element simulated as feedback regarding a decision making by the reinforcement learning agent 220, based on an action determined to optimize the disposition of the semiconductor element, and state information of the customized reinforcement learning environment. The simulation engine 210 may include an environment configuration portion 211, a reinforcement learning environment construction portion 212, and a simulation portion 213.

The environment configuration portion 211 may configure a customized reinforcement learning environment by adding specific constraint or position change information with regard to each object included in design data by using configuration information input from the user terminal 100.

That is, objects included in semiconductor design data, for example, semiconductor elements, standard cell, and wires, are distinguished in terms of characteristics or functions, and s the objects distinguished in terms of characteristics or functions are distinguished by specific colors thereto, thereby preventing the learning range from increasing during reinforcement learning. In addition, the constraint regarding individual objects may be configured during the design process such that various environments can be configured during reinforcement learning.

In addition, various environment conditions may be configured and provided through an object position change such that semiconductor elements are disposed optimally.

The reinforcement learning environment construction portion 212 may analyze object information including logic elements, such as semiconductor elements and standard cells, based on design data including semiconductor netlist information, and may add constraint or position change information configured by the environment configuration portion 211 with regard to each object, thereby generating simulation data constituting a customized reinforcement learning environment.

In addition, the reinforcement learning environment construction portion 212 may request the reinforcement learning agent 220 to provide optimization information for semiconductor element disposition, based on the simulation data.

That is, the reinforcement learning environment construction portion 212 may request the reinforcement learning agent 220 to provide optimization information for disposition of at least one semiconductor element, based on generated simulation data.

The simulation portion 213 may perform simulation that constitutes a reinforcement learning environment regarding semiconductor element disposition, based on actions received from the reinforcement learning agent 220, and may provide the reinforcement learning agent 220 with reward information and state information including semiconductor element disposition information to be used for reinforcement learning.

The reward information may be calculated based on information regarding connection between semiconductor elements and standard cells.

The reinforcement learning agent 220 is configured to perform reinforcement learning, based on state information and reward information received from the simulation engine 210, and to determine an action such that semiconductor element disposition is optimized, and may include a reinforcement learning algorithm.

The reinforcement learning algorithm may use one of a value-based approach scheme and a policy-based approach scheme in order to find out an optimal policy for optimizing rewards. According to the value-based approach scheme, the optimal policy is derived from an optimal value function approximated based on the agent's experience. According to the policy-based approach scheme, an optimal policy separated from value function approximation is learned, and the trained policy is improved in an approximate value function.

In addition, the reinforcement learning algorithm is learned by the reinforcement learning agent 220 to be able to determine actions such that the distance between semiconductor elements, the length of a wire connecting a semiconductor element and a standard cell, and the like are disposed in optimal positions.

Next, a method for reinforcement learning based on a user learning environment in semiconductor design according to an embodiment of the present disclosure will be described.

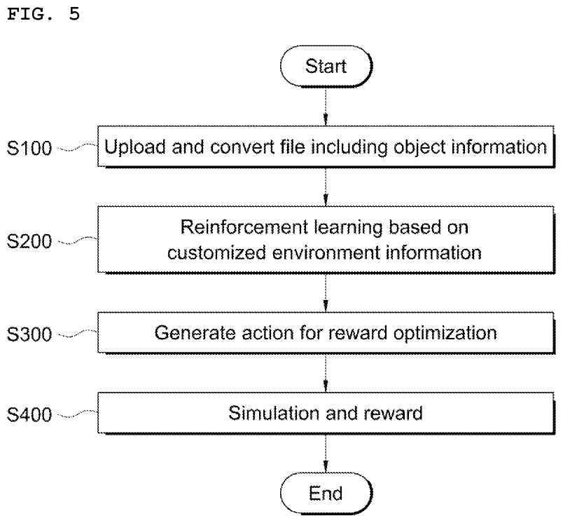

FIG. 5 is a flowchart illustrating a method for reinforcement learning based on a user learning environment in semiconductor design according to an embodiment of the present disclosure.

Referring to FIG. 2 to FIG. 5, according to a method for reinforcement learning based on a user learning environment in semiconductor design according to an embodiment of the present disclosure, the simulation engine 210 of the reinforcement learning server 200 converts, for analysis, information regarding objects including logic elements such as semiconductor elements and standard cells, based on design data including semiconductor netlist information uploaded from the user terminal 100 (S100).

That is, the design data uploaded in step S100 is a semiconductor data file, and includes information regarding semiconductor elements, standard cells, and the like supposed to enter a reinforcement learning state.

Subsequently, the simulation engine 210 of the reinforcement learning server 200 analyzes information regarding objects such as semiconductor elements and standard cells, configures a customized reinforcement learning environment by adding specific constraint or position change information with regard to each analyzed object, based on configuration information input from the user terminal 100, and performs reinforcement learning based on reward information and state information of the customized reinforcement learning environment including semiconductor element disposition information to be used for reinforcement learning (S200).

In addition, the simulation engine 210 configures respective objects to have constraints to be considered during configured semiconductor disposition through a reinforcement learning constraint input portion or the like.

In addition, the simulation engine 210 may configure individual constraints, based on configuration information provided from the user terminal 100.

In addition, the simulation engine 210 may configure constraints provided from the user terminal 100, thereby configuring various customized reinforcement learning environment.

In addition, the simulation engine 210 generates simulation data, based on a customized reinforcement learning environment.

In addition, upon receiving an optimization request for semiconductor element disposition based on simulation data from the simulation engine 210, the reinforcement learning agent 220 of the reinforcement learning server 200 may perform reinforcement learning, based on reward information which is feedback regarding disposition of a target object simulated based on an action that has been decision-made to optimize disposition of semiconductor elements by the reinforcement learning agent 220, and state information of a customized reinforcement learning environment including information regarding disposition of semiconductor elements to be used for reinforcement learning collected from the simulation engine 210.

Subsequently, the reinforcement learning agent 220 determines an action such that disposition of at least one semiconductor element is optimized based on simulation data (S300).

That is, the reinforcement learning agent 220 disposes semiconductor elements by using a reinforcement learning algorithm, and learns actions such that distances from already disposed semiconductor elements, positional relations, the length of wires connecting semiconductor elements and standard cells, and the like are disposed in optimal positions.

Meanwhile, the simulation engine 210 performs simulation regarding semiconductor element disposition, based on actions provided from the reinforcement learning agent 220, and generates reward information as feedback regarding decision making by the reinforcement learning agent 220, based on the result of simulated connection between semiconductor elements and standard cells (S400).

In addition, the reward information in step S400 gives numerical rewards, when the disposition density is to be increased, for example, such that as many rewards are received as possible.

In addition, the reward information may determine distances based on semiconductor element sizes.

Therefore, the user may configure a learning environment and may generate and provide optimal semiconductor element positions through reinforcement learning that uses simulation.

In addition, reinforcement learning may be performed based on learning environments configured by the user, thereby automatically generating semiconductor element positions optimized in various environments.

The present disclosure has been described above with reference to exemplary embodiments, but those skilled in the art will understand that the present disclosure can be variously changed and modified without deviating from the idea and scope of the present disclosure described in the following claims.

In addition, reference numerals used in the claims of the present disclosure are only for clarity and convenience of description and are not limiting in any manner, and the thickness of lines illustrated in the drawings, the size of elements, and the like may be exaggerated for clarity and convenience of description in the process of describing embodiments.

In addition, the above-mentioned terms are designed by considering functions in the present disclosure, and may vary depending on the intent of the user or operator, or practices. Therefore, such terms are to be interpreted based on the overall context of the specification.

In addition, although not explicitly described or illustrated, it is obvious that those skilled in the art can make various types of modifications, including the technical idea of the present disclosure, from descriptions of the present disclosure, and such modifications still fall within the scope of the present disclosure.

In addition, the embodiments described above with reference to accompanying drawings are only for describing the present disclosure, and the scope of the present disclosure is not limited to such embodiments.

### BRIEF DESCRIPTION OF REFERENCE NUMERALS

100: user terminal

200: reinforcement learning server

210: simulation engine

211: environment configuration portion

212: reinforcement learning environment construction portion

213: simulation portion

220: reinforcement learning agent

What is claimed is:

1. An apparatus for reinforcement learning based on a user learning environment in semiconductor design, the apparatus comprising:
a simulation engine (210) configured to analyze object information comprising a semiconductor element and a standard cell based on design data comprising semiconductor netlist information, configure a customized reinforcement learning environment by adding constraint or position change information with regard to each object through configuration information input from a user terminal (100) and the analyzed object information, perform reinforcement learning based on the customized reinforcement learning environment, perform simulation based on an action determined to optimize disposition of at least one semiconductor element and standard cell, and state information of the customized reinforcement learning environment, and provide reward information calculated based on connection information of semiconductor elements and standard cells according to a simulation result as feedback regarding decision making by a reinforcement learning agent (220); and
a reinforcement learning agent (220) configured to perform reinforcement learning based on state information and reward information received from the simulation engine (210), thereby determining an action so as to optimize disposition of semiconductor elements and standard cells,
wherein the simulation engine (210) distinguishes semiconductor elements, standard cells, and wires according to characteristics or functions, and distinguishes, based on addition of specific colors, the objects distinguished according to characteristics or functions, thereby preventing learning ranges from increasing during reinforcement learning, and
wherein the reinforcement learning agent (220) determines an action, by reflecting distances between semiconductor elements and lengths of wires connecting semiconductor elements and standard cells, through learning using a reinforcement learning algorithm such that the semiconductor elements and the standard cells are disposed in optimal positions.

2. The apparatus for reinforcement learning based on a user learning environment in semiconductor design of claim 1, wherein the design data is a semiconductor data file comprising CAD data or netlist data.

3. The apparatus for reinforcement learning based on a user learning environment in semiconductor design of claim 1, wherein the simulation engine (210) comprises:
an environment configuration portion (211) configured to add object-specific constraint or position change information included in design data through configuration information input from the user terminal (100), distinguish semiconductor elements, standard cells, and wires according to characteristics or functions so as to prevent learning ranges from increasing during reinforcement learning, and distinguish, based on addition of specific colors, the objects distinguished according to characteristics or functions, thereby configuring a customized reinforcement learning environment;
a reinforcement learning environment construction portion (212) configured to analyze object information comprising semiconductor elements and standard cells based on design data comprising semiconductor netlist information, generate simulation data constituting a customized reinforcement learning environment by adding constraint or position change information configured by the environment configuration portion (211), and request, based on the simulation data, the reinforcement learning agent (220) to provide optimization information for disposition of at least one semiconductor element and standard cell; and
a simulation portion (213) configured to perform simulation constituting a reinforcement learning environment regarding semiconductor elements and standard cells, based on actions received from the reinforcement learning agent (220), and state information comprising semiconductor element disposition information to be used for reinforcement learning, and provide the reinforcement learning agent (220) with reward information calculated based on connection information of semiconductor elements and standard cells simulated as feedback regarding decision making by the reinforcement learning agent (220).

4. A method for reinforcement learning based on a user learning environment in semiconductor design, the method comprising the steps of:
a) receiving, by a reinforcement learning server (200), design data comprising semiconductor netlist information from a user terminal (100);
b) analyzing, by the reinforcement learning server (200), object information comprising a semiconductor element and a standard cell from the received design data, and configuring a customized reinforcement learning environment by adding constraint or position change information with regard to each object through configuration information input from a user terminal (100), based on the analyzed object information;
c) performing, by the reinforcement learning server (200), reinforcement learning based on reward information and state information of the customized reinforcement learning environment comprising disposition information of semiconductor elements and standard cells to be used for reinforcement learning through a reinforcement learning agent, thereby determining an action so as to optimize disposition of at least one semiconductor element disposition and stand cell disposition; and
d) performing, by the reinforcement learning server (200), simulation constituting a reinforcement learning environment regarding disposition of the semiconductor element and standard cell based on an action, and generating reward information calculated based on connection information of semiconductor elements and standard cells according to a result of performing simulation as feedback regarding decision making by the reinforcement learning agent,
wherein the customized reinforcement learning environment configured in step b) distinguishes semiconductor elements, standard cells, and wires according to characteristics or functions so as to prevent learning ranges from increasing during reinforcement learning, and distinguishes, based on addition of specific colors, the objects distinguished according to characteristics or functions, and
wherein, in step c), the reinforcement learning server (200) determines an action, by reflecting distances between semiconductor elements and lengths of wires connecting semiconductor elements and standard cells, through learning using a reinforcement learning algorithm such that the semiconductor elements and the standard cells are disposed in optimal positions.

5. The method for reinforcement learning based on a user learning environment in semiconductor design of claim 4, wherein the design data in step a) is a semiconductor data file comprising CAD data or netlist data.
